(19) United States
(12) Patent Application Publication
(10) Pub. No.: US 2018/0090053 A1
(43) Pub. Date: Mar. 29, 2018

(54) OUTPUT BUFFER, METHOD FOR OPERATING THE SAME, SOURCE DRIVER AND DISPLAY DEVICE

(71) Applicant: BOE TECHNOLOGY GROUP CO., LTD., Beijing (CN)

(72) Inventors: Airong LIU, Beijing (CN); Zhongyuan WU, Beijing (CN); Chen SONG, Beijing (CN)

(21) Appl. No.: 15/705,637

(22) Filed: Sep. 15, 2017

(30) Foreign Application Priority Data
Sep. 23, 2016 (CN) 201610849253.5

(51) Int. Cl. G09G 3/20

(52) U.S. Cl. CPC G09G 3/2092; G11C 19/00

(57) ABSTRACT

The present disclosure relates to an output buffer, a method for operating the same, a source driver and a display panel. The output buffer includes a matching unit, an input unit and an output unit. The matching unit outputs a first control signal by dynamic element matching technique according to an input signal of the first voltage terminal. The input unit outputs a third control signal based on the first control signal and input signals of the input terminal and the second voltage terminal. The output unit controls an output signal of the output terminal in accordance with the third control signal and input signals of the first signal terminal, the second signal terminal, the third signal terminal, the fourth signal terminal and the second voltage terminal.

### CROSS REFERENCE

The present application is based upon and claims priority to Chinese Patent Application No. 201610849253 filed on Sep. 23, 2016, and the entire contents thereof are incorporated herein by reference.

### TECHNICAL FIELD

The present disclosure relates to the field of display technology, and more particularly to an output buffer, a method for operating the same, a source driver and a display panel.

### BACKGROUND

In existing source drivers, it is often necessary to implement a converting output of a GAMMA voltage using a large number of CMOS (Complementary Metal Oxide Semiconductor) switches (CMOS), to meet the precision requirements of the DAC (Digital to Analog Converter). In order to save the area of the driver chip, it is necessary to reduce the number of CMOS switches in the digital analog converter. Thus, in the prior art, typically a digital-to-analog converter is used for high-order digital-to-analog conversion, and an output buffer is used for low conversion output.

It should be noted that, information disclosed in the above background portion is provided only for better understanding of the background of the present disclosure, and thus it may contain information that does not form the prior art known by those ordinary skilled in the art.

### SUMMARY

In order to solve the above problems, the present disclosure provides an output buffer and a method for operating the same, a source driver and a display panel.

Accordingly, the present disclosure provides an output buffer including a matching unit, an input unit and an output unit, wherein the matching unit is connected to a first voltage terminal and the input unit, respectively, the input unit is connected to an input terminal, a second voltage terminal and the output unit, respectively, and the output unit is connected to the output terminal, a first signal terminal, a second signal terminal, a third signal terminal, a fourth signal terminal, and the second voltage terminal, respectively;

the matching unit is configured to output a first control signal by dynamic element matching technique according to an input signal of the first voltage terminal;

the input unit is configured to output a third control signal based on the first control signal and input signals of the input terminal and the second voltage terminal; and

the output unit is configured to control an output signal of the output terminal in accordance with the third control signal and input signals of the first signal terminal, the second signal terminal, the third signal terminal, the fourth signal terminal and the second voltage terminal.

The present disclosure further provides a source driver including any one of the above output buffer.

The present disclosure further provides a display panel including the above source driver.

The present disclosure further provides a method for operating an output buffer including a matching unit, an input unit and an output unit, wherein the matching unit is connected to a first voltage terminal and the input unit, respectively, the input unit is connected to an input terminal, a second voltage terminal and the output unit, respectively, and the output unit is connected to the output terminal, a first signal terminal, a second signal terminal, a third signal terminal, a fourth signal terminal, and the second voltage terminal, respectively;

the method for operating the output buffer including:

outputting, from the matching unit, a first control signal by a dynamic element matching technique according to an input signal of the first voltage terminal;

outputting, from the input unit, a third control signal based on the first control signal and input signals of the input terminal and the second voltage terminal; and

controlling, by the output unit, an output signal of the output terminal according to the third control signal and input signals of the first signal terminal, the second signal terminal, the third signal terminal, the fourth signal terminal, and the second voltage terminal.

It is to be understood that both the foregoing general description and the following detailed description are exemplary and explanatory only and are not restrictive of the invention, as claimed.

This section provides a summary of various implementations or examples of the technology described in the disclosure, and is not a comprehensive disclosure of the full scope or all features of the disclosed technology.

### BRIEF DESCRIPTION OF THE DRAWINGS

FIG. 1 is a schematic structural diagram of an output buffer according a first embodiment of the present disclosure;

FIG. 2 is a detailed schematic structural diagram of the output buffer illustrated in FIG. 1;

FIG. 3 is a detailed schematic structural diagram of the output buffer illustrated in FIG. 2;

FIG. 4 is a schematic structural diagram of a matching unit according to the first embodiment; and

FIG. 5 is a flow chart of the method for operating the output buffer according to a fourth embodiment of the present disclosure.

### DETAILED DESCRIPTION

For the purpose of making a better understanding of the implementations of the present disclosure, the output buffer and the method for operating the same, the source driver and the display panel provided in the present disclosure will be described in detail with reference to the accompanying drawings.

### The First Embodiment

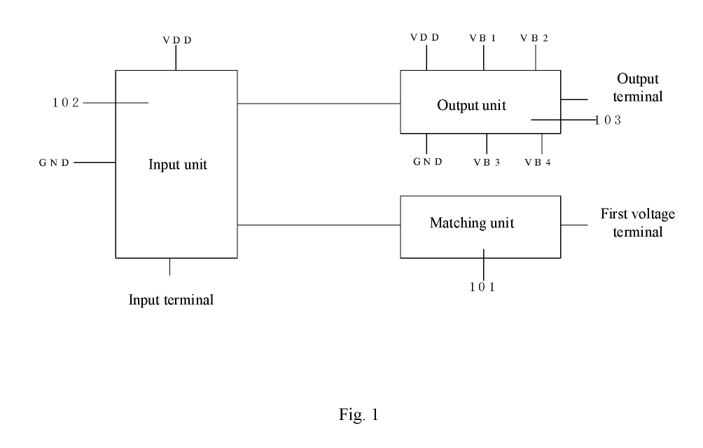

FIG. 1 is a schematic structural diagram of an output buffer according a first embodiment of the present disclosure. As illustrated in FIG. 1, the output buffer includes a matching unit 101, an input unit 102, and an output unit 103. The matching unit 101 is connected to a first voltage terminal and the input unit 102, respectively. The input unit 102 is connected to an input terminal, a second voltage terminal VDD, and the output unit 103, respectively. The output unit 103 is connected to an output terminal, a first signal terminal VB1, a second signal terminal VB2, a third signal terminal VB3, a fourth signal terminal VB4, and the second voltage terminal VDD, respectively.

In the present embodiment, the matching unit 101 outputs a first control signal by a dynamic element matching technique according to the input signal of the first voltage terminal; the input unit 102 outputs a third control signal based on the first control signal and the input signals of the input terminal and the second voltage terminal; and the output unit 103 controls the output signal of the output terminal according to the third control signal and the input signals of the first signal terminal VB1, the second signal terminal VB2, the third signal terminal VB3, the fourth signal terminal VB4, and the second voltage terminal VDD. According to the implementation of the present embodiment, the input transistors may have the same use probability by generating the dynamic control signal by the dynamic element matching technique and taking turns to assign and use the input transistors according to the dynamic control signal. The same probability of use may counterbalance the process deviation, to avoid the serious imbalance between the input transistors due to the process deviation, thereby improving the linearity of the buffer.

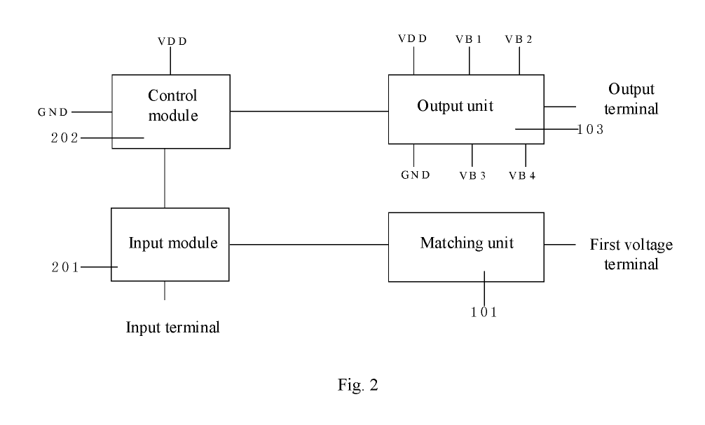

FIG. 2 is a detailed schematic structural view of the output buffer shown in FIG. 1. As shown in FIG. 2, the input unit 102 includes an input module 201 and a control module 202. The input module 201 is connected to the matching unit 101, the input terminal, and the control module 202, respectively, and the control module 202 is connected to the output unit 103 and the second voltage terminal VDD, respectively. The input module 201 makes a selection from different input signals of the input terminal according to the first control signal to output a second control signal. The control module 202 outputs a third control signal according to the second control signal and the input signal of the second voltage terminal. Optionally, the input module 201 is a CMOS switch array, and the matching unit 101 is a dynamic element matching circuit.

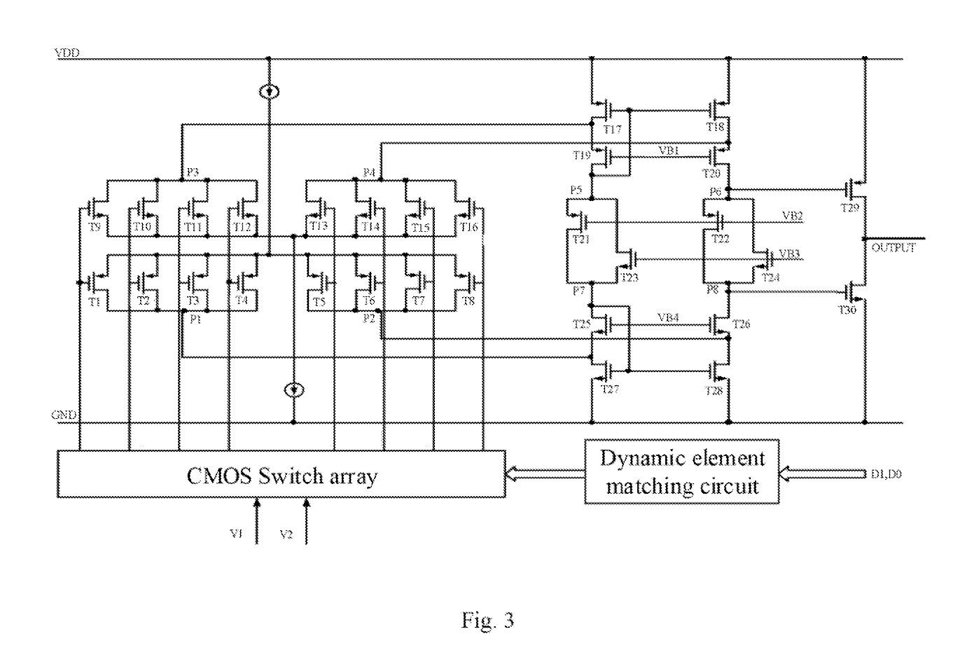

FIG. 3 is a detailed schematic structural view of the output buffer shown in FIG. 2. As illustrated in FIG. 3, the control module 202 includes a first transistor T1, a second transistor T2, a third transistor T3, a fourth transistor T4, a fifth transistor T5, a sixth transistor T6, a seventh transistor T7, an eighth transistor T8, a ninth transistor T9, a tenth transistor T10, an eleventh transistor T11, a twelfth transistor T12, a thirteenth transistor T13, a fourteenth transistor T14, a fifteenth transistor T15, and a sixteenth transistor T16.

In the present embodiment, the gate electrodes of the first transistor T1, the second transistor T2, the third transistor T3, and the fourth transistor T4 are connected to the input module. The first electrodes of the first transistor T1, the second transistor T2, the third transistor T3, and the fourth transistor T4 are connected to the first node. The second electrodes of the first transistor T1, the second transistor T2, the third transistor T3, and the fourth transistor T4 are connected to the second voltage terminal. The gate electrodes of the fifth transistor T5, the sixth transistor T6, the seventh transistor T7, and the eighth transistor T8 are connected to the input module. The first electrodes of the fifth transistor T5, the sixth transistor T6, the seventh transistor T7, and the eighth transistor T8 are connected to the second node. The second electrodes of the fifth transistor T5, the sixth transistor T6, the seventh transistor T7, and the eighth transistor T8 are connected to the second voltage terminal. The gate electrodes of the ninth transistor T9, the tenth transistor T10, the eleventh transistor T11, and the twelfth transistor T12 are connected to the input module. The first electrodes of the ninth transistor T9, the tenth transistor T10, the eleventh transistor T11, and the twelfth transistor T12 are connected to the third node. The second electrodes of the ninth transistor T9, the tenth transistor T10, the eleventh transistor T11, and the twelfth transistor T12 are grounded. The gate electrodes of the thirteenth transistor T13, the fourteenth transistor T14, the fifteenth transistor T15, and the sixteenth transistor T16 are connected to the input module. The first electrodes of the thirteenth transistor T13, the fourteenth transistor T14, the fifteenth transistor T15, and the sixteenth transistor T16 are connected to the fourth node. The second electrodes of the thirteenth transistor T13, the fourteenth transistor T14, the fifteenth transistor T15, and the sixteenth transistor T16 are grounded.

Referring to FIG. 3, the output unit 103 includes a seventeenth transistor T17, an eighteenth transistor T18, a nineteenth transistor T19, a twentieth transistor T20, a twenty-first transistor T21, a twenty-second transistor T22, a twenty-third transistor T23, a twenty-fourth transistor T24, a twenty-fifth transistor T25, a twenty-sixth transistor T26, a twenty-seventh transistor T27, a twenty-eighth transistor T28, a twenty-ninth transistor T29, and a thirtieth transistor T30.

In the present embodiment, the gate electrode of the seventeenth transistor T17 is connected to the fifth node, the first electrode of the seventeenth transistor T17 is connected to the second voltage terminal, and the second electrode of the seventeenth transistor T17 is connected to the third node. The gate electrode of the eighteenth transistor T18 is connected to the fifth node, the first electrode of the eighteenth transistor T18 is connected to the second voltage terminal, and the second electrode of the eighteenth transistor T18 is connected to the fourth node. The gate electrode of the nineteenth transistor T19 is connected to the first signal terminal VB1, the first electrode of the nineteenth transistor T19 is connected to the third node, and the second electrode of the nineteenth transistor T19 is connected to the fifth node. The gate electrode of the twentieth transistor T20 is connected to the first signal terminal VB1, the first electrode of the twentieth transistor T20 is connected to the fourth node, and the second electrode of the twentieth transistor T20 is connected to the sixth node. The gate electrode of the twenty-first transistor T21 is connected to the second signal terminal VB2, the first electrode of the twenty-first transistor T21 is connected to the fifth node, and the second electrode of the twenty-first transistor T21 is connected to the seventh node. The gate electrode of the twenty-second transistor T22 is connected to the second signal terminal VB2, the first electrode of the twenty-second transistor T22 is connected to the sixth node, and the second electrode of the twenty-second transistor T22 is connected to the eighth node.

In the present embodiment, the gate electrode of the twenty-third transistor T23 is connected to the third signal terminal VB3, the first electrode of the twenty-third transistor T23 is connected to the fifth node, and the second electrode of the twenty-third transistor T23 is connected to the seventh node. The gate electrode of the twenty-fourth transistor T24 is connected to the third signal terminal VB3, the first electrode of the twenty-fourth transistor T24 is connected to the sixth node, and the second electrode of the twenty-fourth transistor T24 is connected to the eighth node. The gate electrode of the twenty-fifth transistor T25 is connected to the fourth signal terminal VB4, the first electrode of the twenty-fifth transistor T25 is connected to the seventh node, and the second electrode of the twenty-fifth transistor T25 is connected to the first node. The gate electrode of the twenty-sixth transistor T26 is connected to the fourth signal terminal VB4, the first electrode of the twenty-sixth transistor T26 is connected to the eighth node, and the second electrode of the twenty-sixth transistor T26 is connected to the second node. The gate electrode of the twenty-seventh transistor T27 is connected to the seventh node, the first electrode of the twenty-seventh transistor T27 is connected to the first node, and the second electrode of the twenty-seventh transistor T27 is grounded. The gate electrode of the twenty-eighth transistor T28 is connected to the seventh node, the first electrode of the twenty-eighth transistor T28 is connected to the second node, and the second electrode of the twenty-eighth transistor T28 is grounded. The gate electrode of the twenty-ninth transistor T29 is connected to the sixth node, the first electrode of the twenty-ninth transistor T29 is connected to the second voltage terminal, and the second electrode of the twenty-ninth transistor T29 is connected to the output terminal. The gate electrode of the thirtieth transistor T30 is connected to the eighth node, the first electrode of the thirtieth transistor T30 is connected to the output terminal, and the second electrode of the thirtieth transistor T30 is grounded.

Referring to FIG. 3, an 8 bit DAC and a 2 bit output buffer are taken for example in the present embodiment. In the source driver, the low voltage differential signal is processed by a mini-LVDS (Low-Voltage Differential Signaling) module for data processing and level conversion to form a 10-bit high voltage digital signal, where D1 and D0 are the lowest two bits of the 10-bit high voltage digital signal. In addition, V1 and V2 are the adjacent analog voltages output by the 8-bit DAC. In the present embodiment, the dynamic element matching circuit outputs the first control signal by the dynamic element matching technique according to the input signals D1 and D0 of the first voltage terminal. The first control signal controls the CMOS switch array to select V1 or V2 of the input terminal to output a second control signal. The input transistors may have the same use probability by taking turns to assign and use the input transistors according to the second control signal. The same probability of use may counterbalance the process deviation, to avoid the serious imbalance between the input transistors due to the process deviation, thereby improving the linearity of the buffer.

In the present embodiment, the first transistor T1, the second transistor T2, the third transistor T3, the fourth transistor T4, the fifth transistor T5, the sixth transistor T6, the seventh transistor T7, and the eighth transistor T8 are P type transistors, The ninth transistor T9, the tenth transistor T10, the eleventh transistor T11, the twelfth transistor T12, the thirteenth transistor T13, the fourteenth transistor T14, the fifteenth transistor T15, and the sixteenth transistor T16 are N type transistors. The seventeenth transistor T17, the eighteenth transistor T18, the nineteenth transistor T19, the twentieth transistor T20, the twenty-first transistor T21, the twenty-second transistor T22, and the twenty-ninth transistor T29 are P type transistors. The twenty-third transistor T23, the twenty-fourth transistor T24, the twenty-fifth transistor T25, the twenty-sixth transistor T26, the twenty-seventh transistor T27, the twenty-eighth transistor T28, and the thirtieth transistor T30 are N type transistors.

Optionally, the first transistor T1, the second transistor T2, the third transistor T3, the fourth transistor T4, the fifth transistor T5, the sixth transistor T6, the seventh transistor T7, and the eighth transistor T8 are N type transistors. The ninth transistor T9, the tenth transistor T10, the eleventh transistor T11, the twelfth transistor T12, the thirteenth transistor T13, the fourteenth transistor T14, the fifteenth transistor T15, and the sixteenth transistor T16 are P type transistors. The seventeenth transistor T17, the eighteenth transistor T18, the nineteenth transistor T19, the twentieth transistor T20, the twenty-first transistor T21, the twenty-second transistor T22, and the twenty-ninth transistor T29 are N type transistors. The twenty-third transistor T23, the twenty-fourth transistor T24, the twenty-fifth transistor T25, the twenty-sixth transistor T26, the twenty-seventh transistor T27, the twenty-eighth transistor T28, and the thirtieth transistor T30 are P type transistors.

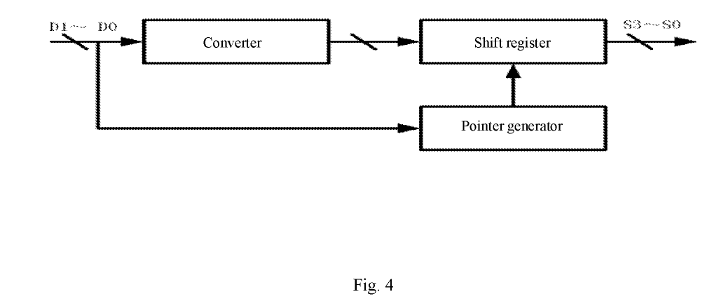

FIG. 4 is a schematic structural diagram of a matching unit according to the first embodiment. As illustrated in FIG. 4, the matching unit 101 includes a converter 301, a pointer generator 302, and a shift register 303. The converter 301 is connected to the first voltage terminal and the shift register 303, respectively. The pointer generator 302 is connected to the first voltage terminal and the shift register 303, respectively. The shift register 303 is connected to the input unit 102, respectively.

In the present embodiment, the converter 301 generates a thermometer code based on an input signal of the first voltage terminal, the pointer generator 302 generates a pointer based on an input signal of the first voltage terminal, and the shift register 303 generates a first control signal based on the thermometer code and the pointer. Referring to FIG. 4, the converter 301 converts D1 and D0 into the thermometer code, and meanwhile the pointer generator 302 generates the pointer of the shift register 303 according to D1 and D0. The shift register 303 generates the first control signal based on the thermometer code and the pointer, and the first control signal controls the CMOS switch array to make an input selection from V1 and V2. The input transistors are assigned and used in turn according to V1 or V2, so that the input transistors have the same usage probability. The same probability of use may counterbalance the process deviation, to avoid the serious imbalance between the input transistors due to the process deviation, thereby improving the linearity of the buffer.

The technical solution provided by the present embodiment can be extended to the M-bit buffer. For the M-bit buffer, the number of element transistors of the control module 201 is 2^{M+2}, and the dynamic element matching circuit outputs the first control signal by the dynamic element matching technique based on the M-bit input data, so that the technical solution of the present disclosure can be extended.

The output buffer provided by the present embodiment includes a matching unit, an input unit, and an output unit. The matching unit is configured to output the first control signal by the dynamic element matching technique according to the input signal of the first voltage terminal. The input unit is configured to output a third control signal based on the first control signal and the input signals of the input terminal and the second voltage terminal. The output unit is configured to control an output signal of the output terminal in accordance with the third control signal and the input signals of the first signal terminal, the second signal terminal, the third signal terminal, the fourth signal terminal and the second voltage terminal. According to the implementation of the present embodiment, the input transistors may have the same use probability by generating the dynamic control signal by the dynamic element matching technique and taking turns to assign and use the input transistors according to the dynamic control signal. The same probability of use may counterbalance the process deviation, to avoid the serious imbalance between the input transistors due to the process deviation, thereby improving the linearity of the buffer.

### The Second Embodiment

The present embodiment provides a source driver including the output buffer provided in the first embodiment, and the details thereof can be described with reference to the first embodiment, which will not be repeated herein.

In the source driver provided in the present embodiment, the output buffer includes a matching unit, an input unit, and an output unit. The matching unit is configured to output the first control signal by the dynamic element matching technique according to the input signal of the first voltage terminal. The input unit is configured to output a third control signal based on the first control signal and the input signals of the input terminal and the second voltage terminal. The output unit is configured to control an output signal of the output terminal in accordance with the third control signal and the input signals of the first signal terminal, the second signal terminal, the third signal terminal, the fourth signal terminal and the second voltage terminal. According to the implementation of the present embodiment, the input transistors may have the same use probability by generating the dynamic control signal by the dynamic element matching technique and taking turns to assign and use the input transistors according to the dynamic control signal. The same probability of use may counterbalance the process deviation, to avoid the serious imbalance between the input transistors due to the process deviation, thereby improving the linearity of the buffer.

### The Third Embodiment

The present embodiment provides a display panel including the source driver provided in the second embodiment, and the details thereof can be described with reference to the second embodiment, which will not be repeated herein.

In the display panel provided in the present embodiment, the output buffer includes a matching unit, an input unit, and an output unit. The matching unit is configured to output the first control signal by the dynamic element matching technique according to the input signal of the first voltage terminal. The input unit is configured to output a third control signal based on the first control signal and the input signals of the input terminal and the second voltage terminal. The output unit is configured to control an output signal of the output terminal in accordance with the third control signal and the input signals of the first signal terminal, the second signal terminal, the third signal terminal, the fourth signal terminal and the second voltage terminal. According to the implementation of the present embodiment, the input transistors may have the same use probability by generating the dynamic control signal by the dynamic element matching technique and taking turns to assign and use the input transistors according to the dynamic control signal. The same probability of use may counterbalance the process deviation, to avoid the serious imbalance between the input transistors due to the process deviation, thereby improving the linearity of the buffer.

### The Fourth Embodiment

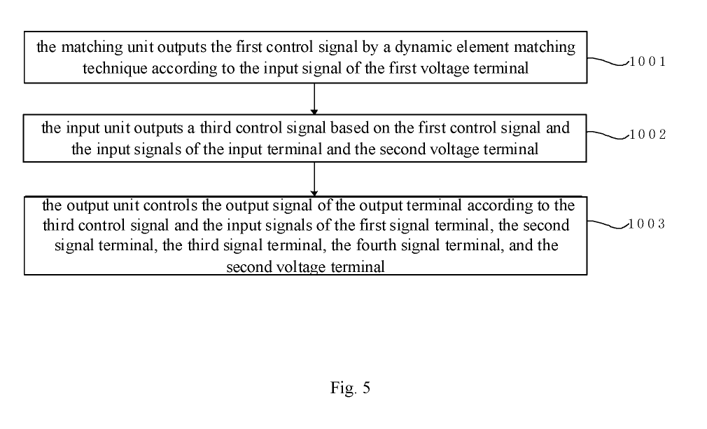

FIG. 5 is a flow chart of the method for operating the output buffer according to the fourth embodiment of the present disclosure. Referring to FIG. 1 and FIG. 5, the output buffer includes a matching unit 101, an input unit 102, and an output unit 103. The matching unit 101 is connected to a first voltage terminal and the input unit 102, respectively. The input unit 102 is connected to an input terminal, a second voltage terminal VDD, and the output unit 103, respectively. The output unit 103 is connected to an output terminal, a first signal terminal VB1, a second signal terminal VB2, a third signal terminal VB3, a fourth signal terminal VB4, and the second voltage terminal VDD, respectively. The method for operating the output buffer includes the steps that follow.

In step 1001, the matching unit outputs the first control signal by a dynamic element matching technique according to the input signal of the first voltage terminal.

In step 1002, the input unit outputs a third control signal based on the first control signal and the input signals of the input terminal and the second voltage terminal.

In the present embodiment, the input unit 102 includes an input module 201 and a control module 202. The input module 201 is connected to the matching unit 101, the input terminal, and the control module 202, respectively, and the control module 202 is connected to the output unit 103 and the second voltage terminal VDD, respectively. The input module 201 makes a selection from different input signals of the input terminal according to the first control signal to output a second control signal. The control module 202 outputs a third control signal according to the second control signal and the input signal of the second voltage terminal. Optionally, the input module 201 is a CMOS switch array, and the matching unit 101 is a dynamic element matching circuit.

In step 1003, the output unit controls the output signal of the output terminal according to the third control signal and the input signals of the first signal terminal VB1, the second signal terminal VB2, the third signal terminal VB3, the fourth signal terminal VB4, and the second voltage terminal.

Referring to FIG. 3, an 8 bit DAC and a 2 bit output buffer are taken for example in the present embodiment. In the source driver, the low voltage differential signal is processed by a mini-LVDS (Low-Voltage Differential Signaling) module for data processing and level conversion to form a 10-bit high voltage digital signal, where D1 and D0 are the lowest two bits of the 10-bit high voltage digital signal. In addition, V1 and V2 are the adjacent analog voltages output by the 8-bit DAC. In the present embodiment, the dynamic element matching circuit outputs the first control signal by the dynamic element matching technique according to the input signals D1 and D0 of the first voltage terminal. The first control signal controls the CMOS switch array to select V1 or V2 of the input terminal to output a second control signal. The input transistors may have the same use probability by taking turns to assign and use the input transistors according to the second control signal. The same probability of use may counterbalance the process deviation, to avoid the serious imbalance between the input transistors due to the process deviation, thereby improving the linearity of the buffer.

Referring to FIG. 4, the matching unit 101 includes a converter 301, a pointer generator 302, and a shift register 303. The converter 301 is connected to the first voltage terminal and the shift register 303, respectively. The pointer generator 302 is connected to the first voltage terminal and the shift register 303, respectively. The shift register 303 is connected to the input unit 102, respectively.

In the present embodiment, the converter 301 generates a thermometer code based on an input signal of the first voltage terminal, the pointer generator 302 generates a pointer based on an input signal of the first voltage terminal, and the shift register 303 generates a first control signal based on the thermometer code and the pointer. Referring to FIG. 4, the converter 301 converts D1 and D0 into the thermometer code, and meanwhile the pointer generator 302 generates the pointer of the shift register 303 according to D1 and D0. The shift register 303 generates the first control signal based on the thermometer code and the pointer, and the first control signal controls the CMOS switch array to make an input selection from V1 and V2. The input transistors are assigned and used in turn according to V1 or V2, so that the input transistors have the same usage probability. The same probability of use may counterbalance the process deviation, to avoid the serious imbalance between the input transistors due to the process deviation, thereby improving the linearity of the buffer.

In the method for operating the output buffer according to the present embodiment, the output buffer includes a matching unit, an input unit, and an output unit. The matching unit is configured to output the first control signal by the dynamic element matching technique according to the input signal of the first voltage terminal. The input unit is configured to output a third control signal based on the first control signal and the input signals of the input terminal and the second voltage terminal. The output unit is configured to control an output signal of the output terminal in accordance with the third control signal and the input signals of the first signal terminal, the second signal terminal, the third signal terminal, the fourth signal terminal and the second voltage terminal. According to the implementation of the present embodiment, the input transistors may have the same use probability by generating the dynamic control signal by the dynamic element matching technique and taking turns to assign and use the input transistors according to the dynamic control signal. The same probability of use may counterbalance the process deviation, to avoid the serious imbalance between the input transistors due to the process deviation, thereby improving the linearity of the buffer.

The present disclosure may have the following advantageous effects.

In the output buffer, the method for operating the same, the source driver and the display panel provided in the present disclosure, the output buffer includes a matching unit, an input unit, and an output unit. The matching unit is configured to output the first control signal by the dynamic element matching technique according to the input signal of the first voltage terminal. The input unit is configured to output a third control signal based on the first control signal and the input signals of the input terminal and the second voltage terminal. The output unit is configured to control an output signal of the output terminal in accordance with the third control signal and the input signals of the first signal terminal, the second signal terminal, the third signal terminal, the fourth signal terminal and the second voltage terminal. According to the implementation of the present disclosure, the input transistors may have the same use probability by generating the dynamic control signal by the dynamic element matching technique and taking turns to assign and use the input transistors according to the dynamic control signal. The same probability of use may counterbalance the process deviation, to avoid the serious imbalance between the input transistors due to the process deviation, thereby improving the linearity of the buffer.

It should be appreciated that, the above embodiments are exemplary implementations for illustrating the principle of the present disclosure only, while the present disclosure is not limited thereto. Various modifications and improvements are possible to those of ordinary skill in the art without departing from the spirit and essence of the present disclosure. All these modifications and improvements will also fall into the protection scope of the present disclosure.

What is claimed is:

1. An output buffer comprising a matching unit, an input unit and an output unit, wherein the matching unit is connected to a first voltage terminal and the input unit, respectively, the input unit is connected to an input terminal, a second voltage terminal and the output unit, respectively, and the output unit is connected to the output terminal, a first signal terminal, a second signal terminal, a third signal terminal, a fourth signal terminal, and the second voltage terminal, respectively;
the matching unit is configured to output a first control signal by dynamic element matching technique according to an input signal of the first voltage terminal;
the input unit is configured to output a third control signal based on the first control signal and input signals of the input terminal and the second voltage terminal; and
the output unit is configured to control an output signal of the output terminal in accordance with the third control signal and input signals of the first signal terminal, the second signal terminal, the third signal terminal, the fourth signal terminal and the second voltage terminal.

2. The output buffer according to claim 1, wherein the input unit comprises an input module and a control module, wherein the input module is connected to the matching unit, the input terminal, and the control module, respectively, and the control module is connected to the output unit and the second voltage terminal, respectively;
the input module is configured to make a selection from different input signals of the input terminal according to the first control signal to output a second control signal; and
the control module is configured to output the third control signal according to the second control signal and the input signal of the second voltage terminal.

3. The output buffer according to claim 2, wherein the control module comprises a first transistor, a second transistor, a third transistor, a fourth transistor, a fifth transistor, a sixth transistor, a seventh transistor, an eighth transistor, a ninth transistor, a tenth transistor, an eleventh transistor, a twelfth transistor, a thirteenth transistor, a fourteenth transistor, a fifteenth transistor, and a sixteenth transistor,
wherein gate electrodes of the first transistor, the second transistor, the third transistor, and the fourth transistor are connected to the input module, first electrodes of the first transistor, the second transistor, the third transistor, and the fourth transistor are connected to a first node, and second electrodes of the first transistor, the second transistor, the third transistor, and the fourth transistor are connected to the second voltage terminal;
wherein gate electrodes of the fifth transistor, the sixth transistor, the seventh transistor, and the eighth transistor are connected to the input module; first electrodes of the fifth transistor, the sixth transistor, the seventh transistor, and the eighth transistor are connected to a second node; and second electrodes of the fifth transistor, the sixth transistor, the seventh transistor, and the eighth transistor are connected to the second voltage terminal;
wherein gate electrodes of the ninth transistor, the tenth transistor, the eleventh transistor, and the twelfth transistor are connected to the input module; first electrodes of the ninth transistor, the tenth transistor, the eleventh transistor, and the twelfth transistor are connected to a third node; and second electrodes of the ninth transistor, the tenth transistor, the eleventh transistor, and the twelfth transistor are grounded;
wherein gate electrodes of the thirteenth transistor, the fourteenth transistor, the fifteenth transistor, and the sixteenth transistor are connected to the input module; first electrodes of the thirteenth transistor, the fourteenth transistor, the fifteenth transistor, and the sixteenth transistor are connected to a fourth node; and second electrodes of the thirteenth transistor, the fourteenth transistor, the fifteenth transistor, and the sixteenth transistor are grounded.

4. The output buffer according to claim 3, wherein the output unit comprises a seventeenth transistor, an eighteenth transistor, a nineteenth transistor, a twentieth transistor, a twenty-first transistor, a twenty-second transistor, a twenty-third transistor, a twenty-fourth transistor, a twenty-fifth transistor, a twenty-sixth transistor, a twenty-seventh transistor, a twenty-eighth transistor, a twenty-ninth transistor, and a thirtieth transistor;
wherein a gate electrode of the seventeenth transistor is connected to a fifth node, a first electrode of the seventeenth transistor is connected to the second voltage terminal, and a second electrode of the seventeenth transistor is connected to the third node;
wherein a gate electrode of the eighteenth transistor is connected to the fifth node, a first electrode of the eighteenth transistor is connected to the second voltage terminal, and a second electrode of the eighteenth transistor is connected to the fourth node;
wherein a gate electrode of the nineteenth transistor is connected to the first signal terminal, a first electrode of the nineteenth transistor is connected to the third node, and a second electrode of the nineteenth transistor is connected to the fifth node;
wherein a gate electrode of the twentieth transistor is connected to the first signal terminal, a first electrode of the twentieth transistor is connected to the fourth node, and a second electrode of the twentieth transistor is connected to a sixth node;
wherein a gate electrode of the twenty-first transistor is connected to the second signal terminal, a first electrode of the twenty-first transistor is connected to the fifth node, and a second electrode of the twenty-first transistor is connected to a seventh node;
wherein a gate electrode of the twenty-second transistor is connected to the second signal terminal, a first electrode of the twenty-second transistor is connected to the sixth node, and a second electrode of the twenty-second transistor is connected to an eighth node.
wherein a gate electrode of the twenty-third transistor is connected to the third signal terminal, a first electrode of the twenty-third transistor is connected to the fifth node, and a second electrode of the twenty-third transistor is connected to the seventh node;
wherein a gate electrode of the twenty-fourth transistor is connected to the third signal terminal, a first electrode of the twenty-fourth transistor is connected to the sixth node, and a second electrode of the twenty-fourth transistor is connected to the eighth node;
wherein a gate electrode of the twenty-fifth transistor is connected to the fourth signal terminal, a first electrode of the twenty-fifth transistor is connected to the seventh node, and a second electrode of the twenty-fifth transistor is connected to the first node;
wherein a gate electrode of the twenty-sixth transistor is connected to the fourth signal terminal, a first electrode of the twenty-sixth transistor is connected to the eighth node, and a second electrode of the twenty-sixth transistor is connected to the second node;
wherein a gate electrode of the twenty-seventh transistor is connected to the seventh node, a first electrode of the twenty-seventh transistor is connected to the first node, and a second electrode of the twenty-seventh transistor is grounded;
wherein a gate electrode of the twenty-eighth transistor is connected to the seventh node, a first electrode of the twenty-eighth transistor is connected to the second node, and a second electrode of the twenty-eighth transistor is grounded;
wherein a gate electrode of the twenty-ninth transistor is connected to the sixth node, a first electrode of the twenty-ninth transistor is connected to the second voltage terminal, and a second electrode of the twenty-ninth transistor is connected to the output terminal; and
wherein a gate electrode of the thirtieth transistor is connected to the eighth node, a first electrode of the thirtieth transistor is connected to the output terminal, and a second electrode of the thirtieth transistor is grounded.

5. The output buffer according to claim 1, wherein the matching unit comprises a converter, a pointer generator, and a shift register, wherein the converter is connected to the first voltage terminal and the shift register, respectively, the pointer generator is connected to the first voltage terminal and the shift register, respectively, and the shift register is connected to the input unit, respectively;
wherein the converter is configured to generate a thermometer code based on the input signal of the first voltage terminal;
the pointer generator is configured to generate a pointer based on the input signal of the first voltage terminal; and
the shift register is configured to generate the first control signal based on the thermometer code and the pointer.

6. The output buffer according to claim 3, wherein the first transistor, the second transistor, the third transistor, the fourth transistor, the fifth transistor, the sixth transistor, the seventh transistor, and the eighth transistor are P type transistors, and
the ninth transistor, the tenth transistor, the eleventh transistor, the twelfth transistor, the thirteenth transistor, the fourteenth transistor, the fifteenth transistor, and the sixteenth transistor are N type transistors.

7. The output buffer according to claim 3, wherein the first transistor, the second transistor, the third transistor, the fourth transistor, the fifth transistor, the sixth transistor, the seventh transistor, and the eighth transistor are N type transistors, and
the ninth transistor, the tenth transistor, the eleventh transistor, the twelfth transistor, the thirteenth transistor, the fourteenth transistor, the fifteenth transistor, and the sixteenth transistor are P type transistors.

8. The output buffer according to claim 4, wherein the seventeenth transistor, the eighteenth transistor, the nineteenth transistor, the twentieth transistor, the twenty-first transistor, the twenty-second transistor, and the twenty-ninth transistor are P type transistors, and
the twenty-third transistor, the twenty-fourth transistor, the twenty-fifth transistor, the twenty-sixth transistor, the twenty-seventh transistor, the twenty-eighth transistor, and the thirtieth transistor are N type transistors.

9. The output buffer according to claim 4, wherein the seventeenth transistor, the eighteenth transistor, the nineteenth transistor, the twentieth transistor, the twenty-first transistor, the twenty-second transistor, and the twenty-ninth transistor are N type transistors, and
the twenty-third transistor, the twenty-fourth transistor, the twenty-fifth transistor, the twenty-sixth transistor, the twenty-seventh transistor, the twenty-eighth transistor, and the thirtieth transistor are P type transistors.

10. A source driver comprising the output buffer according to claim 1.

11. The source driver according to claim 10, wherein the input unit comprises an input module and a control module, wherein the input module is connected to the matching unit, the input terminal, and the control module, respectively, and the control module is connected to the output unit and the second voltage terminal, respectively;
the input module is configured to make a selection from different input signals of the input terminal according to the first control signal to output a second control signal; and
the control module is configured to output the third control signal according to the second control signal and the input signal of the second voltage terminal.

12. The source driver according to claim 11, wherein the control module comprises a first transistor, a second transistor, a third transistor, a fourth transistor, a fifth transistor, a sixth transistor, a seventh transistor, an eighth transistor, a ninth transistor, a tenth transistor, an eleventh transistor, a twelfth transistor, a thirteenth transistor, a fourteenth transistor, a fifteenth transistor, and a sixteenth transistor,
wherein gate electrodes of the first transistor, the second transistor, the third transistor, and the fourth transistor are connected to the input module, first electrodes of the first transistor, the second transistor, the third transistor, and the fourth transistor are connected to a first node, and second electrodes of the first transistor, the second transistor, the third transistor, and the fourth transistor are connected to the second voltage terminal;
wherein gate electrodes of the fifth transistor, the sixth transistor, the seventh transistor, and the eighth transistor are connected to the input module; first electrodes of the fifth transistor, the sixth transistor, the seventh transistor, and the eighth transistor are connected to a second node; and second electrodes of the fifth transistor, the sixth transistor, the seventh transistor, and the eighth transistor are connected to the second voltage terminal;
wherein gate electrodes of the ninth transistor, the tenth transistor, the eleventh transistor, and the twelfth transistor are connected to the input module; first electrodes of the ninth transistor, the tenth transistor, the eleventh transistor, and the twelfth transistor are connected to a third node; and second electrodes of the ninth transistor, the tenth transistor, the eleventh transistor, and the twelfth transistor are grounded;
wherein gate electrodes of the thirteenth transistor, the fourteenth transistor, the fifteenth transistor, and the sixteenth transistor are connected to the input module; first electrodes of the thirteenth transistor, the fourteenth transistor, the fifteenth transistor, and the sixteenth transistor are connected to a fourth node; and second electrodes of the thirteenth transistor, the fourteenth transistor, the fifteenth transistor, and the sixteenth transistor are grounded.

13. The source driver according to claim 12, wherein the output unit comprises a seventeenth transistor, an eighteenth transistor, a nineteenth transistor, a twentieth transistor, a twenty-first transistor, a twenty-second transistor, a twenty-third transistor, a twenty-fourth transistor, a twenty-fifth transistor, a twenty-sixth transistor, a twenty-seventh transistor, a twenty-eighth transistor, a twenty-ninth transistor, and a thirtieth transistor;
wherein a gate electrode of the seventeenth transistor is connected to a fifth node, a first electrode of the seventeenth transistor is connected to the second voltage terminal, and a second electrode of the seventeenth transistor is connected to the third node;
wherein a gate electrode of the eighteenth transistor is connected to the fifth node, a first electrode of the eighteenth transistor is connected to the second voltage terminal, and a second electrode of the eighteenth transistor is connected to the fourth node;
wherein a gate electrode of the nineteenth transistor is connected to the first signal terminal, a first electrode of the nineteenth transistor is connected to the third node, and a second electrode of the nineteenth transistor is connected to the fifth node;
wherein a gate electrode of the twentieth transistor is connected to the first signal terminal, a first electrode of the twentieth transistor is connected to the fourth node, and a second electrode of the twentieth transistor is connected to a sixth node;
wherein a gate electrode of the twenty-first transistor is connected to the second signal terminal, a first electrode of the twenty-first transistor is connected to the fifth node, and a second electrode of the twenty-first transistor is connected to a seventh node;
wherein a gate electrode of the twenty-second transistor is connected to the second signal terminal, a first electrode of the twenty-second transistor is connected to the sixth node, and a second electrode of the twenty-second transistor is connected to an eighth node;
wherein a gate electrode of the twenty-third transistor is connected to the third signal terminal, a first electrode of the twenty-third transistor is connected to the fifth node, and a second electrode of the twenty-third transistor is connected to the seventh node;
wherein a gate electrode of the twenty-fourth transistor is connected to the third signal terminal, a first electrode of the twenty-fourth transistor is connected to the sixth node, and a second electrode of the twenty-fourth transistor is connected to the eighth node;
wherein a gate electrode of the twenty-fifth transistor is connected to the fourth signal terminal, a first electrode of the twenty-fifth transistor is connected to the seventh node, and a second electrode of the twenty-fifth transistor is connected to the first node;
wherein a gate electrode of the twenty-sixth transistor is connected to the fourth signal terminal, a first electrode of the twenty-sixth transistor is connected to the eighth node, and a second electrode of the twenty-sixth transistor is connected to the second node;
wherein a gate electrode of the twenty-seventh transistor is connected to the seventh node, a first electrode of the twenty-seventh transistor is connected to the first node, and a second electrode of the twenty-seventh transistor is grounded;
wherein a gate electrode of the twenty-eighth transistor is connected to the seventh node, a first electrode of the twenty-eighth transistor is connected to the second node, and a second electrode of the twenty-eighth transistor is grounded;
wherein a gate electrode of the twenty-ninth transistor is connected to the sixth node, a first electrode of the twenty-ninth transistor is connected to the second voltage terminal, and a second electrode of the twenty-ninth transistor is connected to the output terminal; and
wherein a gate electrode of the thirtieth transistor is connected to the eighth node, a first electrode of the thirtieth transistor is connected to the output terminal, and a second electrode of the thirtieth transistor is grounded.

14. The source driver according to claim 10, wherein the matching unit comprises a converter, a pointer generator, and a shift register, wherein the converter is connected to the first voltage terminal and the shift register, respectively, the pointer generator is connected to the first voltage terminal and the shift register, respectively, and the shift register is connected to the input unit, respectively;
wherein the converter is configured to generate a thermometer code based on the input signal of the first voltage terminal;
the pointer generator is configured to generate a pointer based on the input signal of the first voltage terminal; and
the shift register is configured to generate the first control signal based on the thermometer code and the pointer.

15. The source driver according to claim 12, wherein the first transistor, the second transistor, the third transistor, the fourth transistor, the fifth transistor, the sixth transistor, the seventh transistor, and the eighth transistor are first conductive type transistors, and
the ninth transistor, the tenth transistor, the eleventh transistor, the twelfth transistor, the thirteenth transistor, the fourteenth transistor, the fifteenth transistor, and the sixteenth transistor are second conductive type transistors.

16. The source driver according to claim 13, wherein the seventeenth transistor, the eighteenth transistor, the nineteenth transistor, the twentieth transistor, the twenty-first transistor, the twenty-second transistor, and the twenty-ninth transistor are first conductive type transistors, and
the twenty-third transistor, the twenty-fourth transistor, the twenty-fifth transistor, the twenty-sixth transistor, the twenty-seventh transistor, the twenty-eighth transistor, and the thirtieth transistor are second conductive type transistors.

17. A display panel, comprising the source driver according to claim 10.

18. A method for operating an output buffer comprising a matching unit, an input unit and an output unit, wherein the matching unit is connected to a first voltage terminal and the input unit, respectively, the input unit is connected to an input terminal, a second voltage terminal and the output unit, respectively, and the output unit is connected to the output terminal, a first signal terminal, a second signal terminal, a third signal terminal, a fourth signal terminal, and the second voltage terminal, respectively;
the method for operating the output buffer comprising:
outputting, from the matching unit, a first control signal by a dynamic element matching technique according to an input signal of the first voltage terminal;
outputting, from the input unit, a third control signal based on the first control signal and input signals of the input terminal and the second voltage terminal; and
controlling, by the output unit, an output signal of the output terminal according to the third control signal and input signals of the first signal terminal, the second signal terminal, the third signal terminal, the fourth signal terminal, and the second voltage terminal.

19. The method for operating an output buffer according to claim 18, wherein the input unit comprises an input module and a control module, wherein the input module is connected to the matching unit, the input terminal, and the control module, respectively, and the control module is connected to the output unit and the second voltage terminal, respectively,
wherein the outputting, from the input unit, a third control signal based on the first control signal and input signals of the input terminal and the second voltage terminal comprises:
making a selection, by the input module, from different input signals of the input terminal according to the first control signal to output a second control signal; and
outputting, from the control module, the third control signal according to the second control signal and the input signal of the second voltage terminal.

20. The method for operating an output buffer according to claim 18, wherein the matching unit comprises a converter, a pointer generator, and a shift register, wherein the converter is connected to the first voltage terminal and the shift register, respectively, the pointer generator is connected to the first voltage terminal and the shift register, respectively, and the shift register is connected to the input unit, respectively,
wherein the outputting, from the matching unit, a first control signal by a dynamic element matching technique according to an input signal of the first voltage terminal comprises:
generating, by the converter, a thermometer code based on the input signal of the first voltage terminal;
generating, by the pointer generator, a pointer based on the input signal of the first voltage terminal; and
generating, by the shift register, the first control signal based on the thermometer code and the pointer.
